(19) United States
(12) Patent Application Publication
(10) Pub. No.: US 2008/0157159 A1
(43) Pub. Date: Jul. 3, 2008

(54) HIGHLY TUNABLE METAL-ON-SEMICONDUCTOR VARACTOR

(75) Inventors: Terence B. Hook, Jericho, VT (US); Jae-Eun Park, Wappingers Falls, NY (US)

Correspondence Address: SCULLY, SCOTT, MURPHY & PRESSER, P.C., 400 GARDEN CITY PLAZA, Suite 300, GARDEN CITY, NY, 11530, US

(73) Assignee: INTERNATIONAL BUSINESS MACHINES CORPORATION, Armonk, NY (US)

(21) Appl. No.: 11/617,322

(22) Filed: Dec. 28, 2006

(51) Int. Cl. H01L 29/93

(52) U.S. Cl. 257/312; 257/E29.344

(57) ABSTRACT

A metal-on-semiconductor varactor with a high value of Cₘₐₓ/Cₘᵢₙ comprises a semiconductor bottom plate with an array of semiconductor pillars. The pillars may be in an accumulation mode to provide a high capacitance or in a depletion mode to provide a low capacitance. The maximum capacitance in an accumulation mode is primarily determined by the capacitance of the semiconductor pillars. The minimum capacitance in a depletion mode is primarily determined by a capacitor formed on an inter-pillar semiconductor surface between the semiconductor pillars. The minimum capacitance, and hence the value of Cₘₐₓ/Cₘᵢₙ may be tuned by adjusting process parameters, design parameters and by alterations in the MOS varactor structure such as forming a highly doped semiconductor layer beneath the inter-pillar semiconductor surface or forming a plate insulator.

### FIELD OF THE INVENTION

The present invention relates to a semiconductor structure, and particularly to metal-on-semiconductor (MOS) varactor with a highly tunable (Cₘₐₓ/Cₘᵢₙ).

### BACKGROUND OF THE INVENTION

A varactor is a semiconductor device having a voltage-sensitive capacitance. Frequently, the space-charge region and the accumulation at the surface of a semiconductor contacting an insulator are altered as a function of applied voltage to produce a bias-dependent capacitance.

Varactors are used in semiconductor applications, for example, to construct voltage-controlled oscillators (VCO). Use of a VCO is a cost-effective method for generating a tunable stable frequency without employing a circuit with multiple oscillators. U.S. Pat. No. 7,129,801 to Wu shows an exemplary use of a varactor in a VCO circuit. A VCO is a versatile basic building block for constructing transceiver circuitry, phase locked loop (PLL) circuitry, and other wireless communication circuitry.

The tuning characteristic of a varactor can affect their circuit performance significantly. The Q factor of a VCO circuit depends on the ratio of the maximum capacitance to the minimum capacitance, that is, Cₘₐₓ/Cₘᵢₙ. While the use of a modified trench capacitor, which is commonly used in dynamic random access memory (DRAM) devices, as a varactor is known in the prior art, the ratio of a maximum capacitance to a minimum capacitance is relatively low for this type of varactors with a poor processing control to obtain intended tuning ratio.

High tunability of a VCO circuit requires a high Q factor, and consequently a high number for Cₘₐₓ/Cₘᵢₙ. Therefore, there exists a need for a semiconductor varactor that provides a high number for the ratio of a maximum capacitance to a minimum capacitance.

Furthermore, requirements for the value of Cₘₐₓ/Cₘᵢₙ depend on the nature of the semiconductor circuit. Therefore, there exists a need for the capability of altering the value of Cₘₐₓ/Cₘᵢₙ by adjusting process parameters, design parameters, or alterations in the semiconductor varactor structure.

### SUMMARY OF THE INVENTION

The present invention addresses the needs described above by providing a metal-on-semiconductor (MOS) varactor with a high value of Cₘₐₓ/Cₘᵢₙ (tuning ratio) and controllability of the tuning ratio

Specifically, the present invention provides a MOS varactor comprising at least one semiconductor pillar that may operate in an accumulation mode or in a depletion mode.

According to the present invention, a metal-oxide-semiconductor (MOS) varactor structure is provided. The MOS varactor structure comprises:

a semiconductor bottom plate having at least one semiconductor pillar and an inter-pillar semiconductor surface, wherein the inter-pillar semiconductor surface contacts at least one sidewall surface of each of the at least one semiconductor pillar;

a capacitor dielectric contacting the at least one semiconductor pillar and the inter-pillar semiconductor surface; and

a conductive top plate contacting the capacitor dielectric.

In some embodiments, the capacitor dielectric contacts the inter-pillar semiconductor surface. In another embodiment, the capacitor dielectric does not contact the inter-pillar semiconductor surface. Instead, a plate insulator contacts the inter-pillar semiconductor surface and contacts at least one sidewall surface of each of the at least one semiconductor pillar.

The at least one semiconductor pillar preferably comprises an array of semiconductor pillars in a row and column arrangement. The array may be a rectangular array or an alternate array such as one in a honeycomb style arrangement.

The at least one semiconductor pillar is electrically connected to a bottom semiconductor. The inter-pillar semiconductor surface is a portion of the surface of the bottom semiconductor. Both the at least one semiconductor pillar and the bottom semiconductor comprise a doped semiconductor material of either p-type or n-type. The capacitor dielectric comprises a dielectric material. The conductive top plate comprises a conductive material such as heavily doped polysilicon.

The MOS varactor may operate in an accumulation mode or in a depletion mode. During operation in an accumulation mode, a thin majority carrier layer is formed beneath the capacitor dielectric. The capacitance of the MOS varactor is the sum of the capacitance of component capacitors at the top and at the sidewalls of each of the at least one semiconductor pillar, and the capacitance of a component capacitor at the inter-pillar semiconductor surface. During operation in a depletion mode, the at least one pillar is completely depleted, i.e., devoid of free mobile charges, and the capacitance of the MOS varactor is substantially determined by the capacitance of the component capacitor at the inter-pillar semiconductor surface.

The mode of the MOS varactor changes between an accumulation mode and a depletion mode with application of a modest voltage bias across the two electrodes, typically, on the order of the band gap of the semiconductor substrate, which in the case of silicon is 1.10V. In the accumulation mode, the capacitance of the MOS varactor rapidly approaches the maximum capacitance with an increase in the magnitude of the voltage bias. Also, in the depletion mode Cₘₐₓ, the capacitance of the MOS varactor rapidly approaches the minimum capacitance Cₘᵢₙ with an increase in the magnitude of the voltage bias.

The minimum capacitance Cₘᵢₙ, and consequently the ratio of the maximum capacitance to the minimum capacitance Cₘₐₓ/Cₘᵢₙ may be tuned by changing the doping concentration of the semiconducting bottom plate, by changing the thickness of the capacitor dielectric, by changing the ratio of the total surface area of the semiconductor pillars to the area of the inter-pillar semiconductor surface contacting the capacitor dielectric, and/or changing the aspect ratio of the at least one semiconductor pillar, i.e., the ratio of the height of the at least one semiconductor pillar to a typical lateral dimension of the at least one semiconductor pillar.

The minimum capacitance Cₘᵢₙ, and consequently the ratio of the maximum capacitance to the minimum capacitance Cₘₐₓ/Cₘᵢₙ may also be tuned by structural alterations in a MOS varactor structure. For example, a heavily doped semiconductor layer is formed in the semiconductor bottom plate and contacts the bottom of the at least one semiconductor pillar. Both a volume beneath the bottom(s) of the at least one semiconductor pillar and a volume beneath the inter-pillar semiconductor surface may be heavily doped. Alternately, only a volume beneath the inter-pillar semiconductor surface may be heavily doped. In both of these cases, the minimum capacitance increases. Alternatively, a plate insulator may be formed on the inter-pillar semiconductor surface and contact at least one sidewall surface of each of the at least one semiconductor pillar. In this case, the minimum capacitance decreases.

### BRIEF DESCRIPTION OF THE DRAWINGS

FIG. 1A is a top-down cross-sectional view of a metal-on-semiconductor (MOS) varactor in the plane of A-A′ in FIG. 1B according to a first embodiments of the present invention.

FIG. 1B is a vertical cross-sectional view of a metal-on-semiconductor (MOS) varactor in the plane of B-B′ in FIG. 1A according to the first embodiments of the present invention.

FIG. 2 is a vertical cross-sectional view of a metal-on-semiconductor (MOS) varactor in the plane of B-B′ in FIG. 1A in an accumulation mode with P type substrate according to the first embodiments of the present invention. (Polarity would be reversed for an N type substrate.)

FIG. 3 is a vertical cross-sectional view of a metal-on-semiconductor (MOS) varactor in the plane of B-B′ in FIG. 1A in a depletion mode according to the first embodiments of the present invention.

FIG. 4 is a vertical cross-sectional view of a metal-on-semiconductor (MOS) varactor according to the second embodiments of the present invention.

FIG. 5 is a vertical cross-sectional view of a metal-on-semiconductor (MOS) varactor according to the third embodiments of the present invention.

FIG. 6 is a vertical cross-sectional view of a metal-on-semiconductor (MOS) varactor according to the fourth embodiments of the present invention.

FIG. 7 is a graph of gate voltage versus capacitance. The units on both axes are arbitrary.

### DETAILED DESCRIPTION OF THE INVENTION

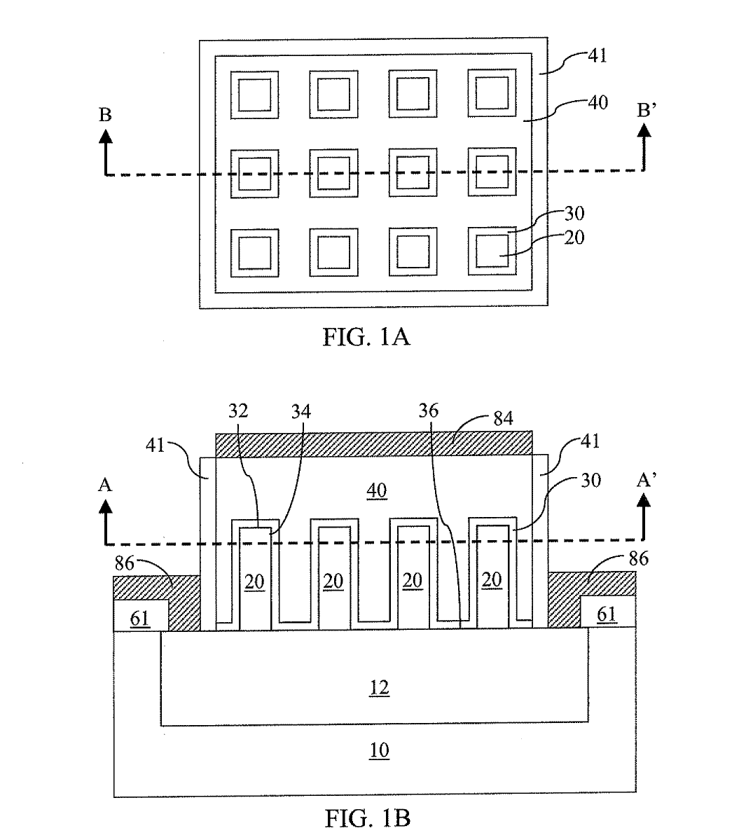

Referring to FIGS. 1A and 1B, a MOS varactor according to the first embodiment of the present invention is shown. FIG. 1A is a top-down cross-sectional view taken in the plane of A-A′ in FIG. 1B and FIG. 1B is a vertical cross-sectional view taken in the plane of B-B′ in FIG. 1A.

The MOS varactor comprises a semiconductor bottom plate that has at least one semiconductor pillar 20 and a bottom semiconductor 12. The bottom semiconductor 12 contacts bottom surfaces of the at least one semiconductor pillar 20. The bottom semiconductor 12 is located within a semiconductor substrate 10. The portion of the surface of the bottom semiconductor 12 that does not contact the semiconductor substrate 10 or the semiconductor pillar 20 is an inter-pillar semiconductor surface 36.

While a 3×4 rectangular array of semiconductor pillars 20 is used in figures for the purposes of describing the present invention, the geometrical arrangement of the at least one semiconductor pillar 20 is not limited to a rectangular array. One semiconductor pillar or a plurality of semiconductor pillars in an arbitrary array formation may be employed to practice the present invention.

The at least one semiconductor pillar 20 comprises semiconductor material and is formed on the bottom semiconductor 12. Preferably, both the at least one semiconductor pillar 20 and the bottom semiconductor 12 are single crystalline semiconductors. Most preferably, the at least one semiconductor pillar 20 and the bottom semiconductor 12 are of the same semiconductor material and are epitaxially aligned among themselves.

The bottom semiconductor 12 and the at least one semiconductor pillar 20 are doped with the same type of dopants. The types of doping may be the same or opposite between the bottom semiconductor 12 and the semiconductor substrate 10. If the doping types are the same between the bottom semiconductor 12 and the semiconductor substrate 10, the doping concentration in the bottom semiconductor 12 is higher than the doping concentration in the semiconductor substrate 10.

The doping concentration of the at least one semiconductor pillar 20 may be higher than or substantially the same as the doping concentration of the bottom semiconductor 12. Preferably, the doping concentration of the at least one semiconductor pillar 20 is substantially the same as the doping concentration of the bottom semiconductor 12.

The at least one semiconductor pillar 20 and the bottom semiconductor 12 comprise a doped single-crystalline semiconductor material having a doping concentration in the range from about 1.0×10¹⁶/cm³ to about 2.0×10²⁰/cm³, and preferably in the range from about 1.0×10¹⁷/cm³ to about 5.0×10¹⁸/cm³. A relatively low doping concentration range is preferred for the at least one semiconductor pillar to achieve a high Cₘₐₓ/Cₘᵢₙ ratio. A relatively high doping concentration range is preferred to achieve a high capacitance density, that is, capacitance per unit semiconductor area used in the MOS varactor structure. The preferred doping concentration according to the present invention is substantially lower than the doping concentration of buried plate in a typical DRAM capacitor, which is from about 1.0×10¹⁹/cm³ to about 1.0×10²⁰/cm³ near the capacitor dielectric (node dielectric).

The inter-pillar semiconductor surface 36 is not covered by any of the at least one semiconductor pillar 20. The inter-pillar semiconductor surface 36 is a two dimensional surface with non-adjoining holes, in which the number of the non-adjoining holes is the number of the at least one semiconducting pillar 20 and the shape of each hole match the shape of the bottom of each of the at least one semiconductor pillar 20. The inter-pillar semiconductor surface 36 adjoins at least one sidewall surface 34 of each of the at least one semiconductor pillar 20.

Each of the at least one semiconductor pillar 20 may have a polygonal or elliptical horizontal cross-section and preferably has a height at least on the order of a minor lateral dimension. More preferably, the height of the at least one semiconductor pillar 20 is greater than the minor lateral dimension. The minor lateral dimension is the diameter of a circle that contacts a boundary of the horizontal cross-sectional area of the at least one semiconductor pillar 20 and fits inside the horizontal cross-sectional area. For example, for a square shape boundary in the horizontal cross-section of the at least one semiconductor pillar 20, as shown in FIG. 1A, the minor lateral dimension is the diameter of the circle that contacts the square shape boundary from the inside, which is identical to the length of a side of the square. If the cross-section is rectangular or polygonal, similar circles may be fitted inside the cross-sectional area to define a minor lateral dimension. If the cross-sectional area is elliptical, the diameter of the circle is the distance between the two minor vertices. A minor lateral dimension can be defined similarly in an arbitrary cross-sectional shape.

Each of the at least one semiconductor pillar 20 has a top surface 32 and also at least one sidewall surface 34, which may be multiple flat vertical surfaces or at least one curved vertical surface depending on the cross-sectional area of the semiconductor pillar 20. The height of the at least one semiconductor pillar is defined as the vertical distance between the top surface 32 and the inter-pillar semiconductor surface 36.

Preferably, the cross-sectional area of each of the at least one semiconductor pillar 20 is substantially a rectangle with two major sides with a first length and two minor sides with a second length, in which the first length is not less than the second length. In this case, the minor lateral dimension is the second length. Preferably, the height of the at least one semiconductor pillar 20 is greater than the second length.

In an exemplary illustration of dimensions, the cross-section of the semiconductor pillars may be a square with the length of a side in the range from about 60 nm to about 5000 nm, preferably in the range from about 100 nm to about 300 nm. The height of each of the semiconductor pillar may be in the range from about 100 nm to about 8000 nm, preferably in the range from about 150 nm to about 2000 nm. The ratio of the height of the semiconductor pillars to the length of the side, which is the minor lateral dimension, may be in the range from about 1 to about 30, preferably in the range from about 2 to about 10. The above exemplary illustration is not a limitation on dimensions, but is a demonstration of practicability of the present invention.

The profiles of the at least one semiconductor pillar 20 may be substantially vertical, that is, the first length is substantially the same among the at least one semiconductor pillar 20 irrespective of the height of the cross-section, that is, irrespective of the vertical level at which the cross-section is taken, and the second length is substantially the same among the at least one semiconductor pillar 20 irrespective of the height of the cross-section. Alternately, a slight taper due to process limitations may be present in the profiles of the at least one semiconductor pillar 20.

The at least one semiconductor pillars 20 may be formed by lithographically patterning and exposing the area outside of the at least one semiconductor pillar 20, followed by a reactive ion etch (RIE) to transfer the pattern in a photoresist into a semiconductor material. Alternatively, an insulator may be deposited on a semiconductor surface and patterned to remove the insulator material from the area that corresponds to locations for the at least one semiconductor pillar 20 to be formed. This is followed by a deposition of a semiconductor material. In this case, selective epitaxial deposition is preferred since the resulting at least one semiconductor pillar 20 is epitaxially aligned to the underlying bottom semiconductor 12. Chemical mechanical planarization (CMP) of the surface of the semiconductor structure may be employed as needed to planarize the semiconductor structure. Optionally, shallow trench isolation (not shown) may be formed prior to or after the formation of the at least one semiconductor pillar 20 to provide electrical insulation to the bottom semiconductor 12.

The capacitor dielectric 30 comprises dielectric material. For example, the capacitor dielectric 30 may be a silicon nitride, a stack of silicon nitride and a silicon oxide, a stack of silicon nitride, silicon oxide, and silicon oxide (ONO stack), a high-K dielectric layer, or a combination thereof. The capacitor dielectric 30 may be formed by thermal conversion of an underlying semiconductor material, such as thermal oxidation or thermal nitridation, or by conformal chemical vapor deposition (CVD) of new material such as low pressure chemical vapor deposition.

An insulator layer 61 may be deposited and patterned to provide electrical insulation to the bottom semiconductor 12 at this point.

A top conductive plate 40 is formed over the capacitor dielectric 30 by deposition of a top conductive plate material, application of a photoresist and lithographic patterning, and etching of the top conductive plate material. If multiple semiconductor pillars are present, the space between each of the multiple semiconductor pillars is filled during the deposition of the top conductive plate material. As necessary, chemical mechanical planarization may be performed.

The top conductive plate 40 comprises a conductive material, for example, heavily doped polysilicon, metal, or metal silicides. The choice of the material in the top conductive plate 40 determines the work function on the top conductive plate side of the capacitor dielectric 30, and hence affects the level of bias across the capacitor dielectric 30 needed to induce an accumulation mode or a depletion mode. Preferably, the top semiconductor material 40 comprises a heavily doped semiconductor material. More preferably, the conductive top plate 40 comprises doped polysilicon having a doping concentration in the range from about 1.0×10¹⁸/cm³ to about 3.0×10²¹/cm³. The top conductive plate 40 may be doped either with p-type dopants or n-type dopants.

Preferably, a dielectric spacer 41 is formed around the top conductive plate 40. Also, an insulator layer 61 can be formed at this point concurrently with the formation of the spacer 41 instead of forming an insulator layer 61 prior to the formation of the top conductive plate 40.

Thereafter, bottom contacts 86 and top contact 84 are formed preferably by forming semiconductor metal alloys, e.g., metal silicides in the case of silicon material in the bottom semiconductor 12 and top conductive plate 40. The bottom contact 86 electrically contacts the bottom semiconductor 12 and the top contact 84 electrically contacts the top conductive layer 40.

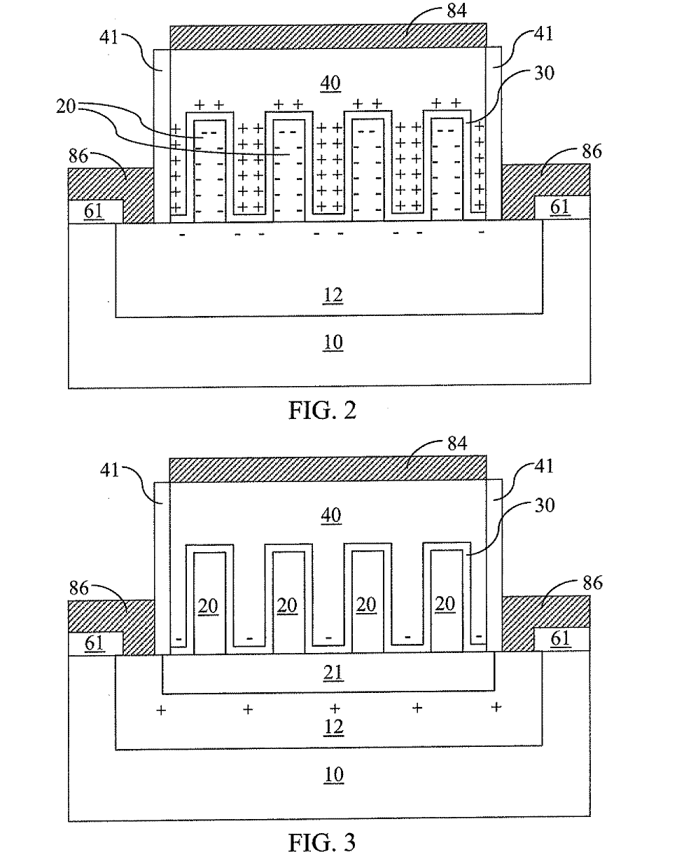

The operation of the MOS varactor according to the present invention is described in FIGS. 2-3. FIG. 2 shows a MOS varactor according to the first embodiment of the present invention in an accumulation mode and FIG. 3 shows the MOS varactor in a depletion mode.

Referring to FIG. 2, the MOS varactor may be put in an accumulation mode by applying a voltage bias across the capacitor dielectric 30 such that the majority carriers are attracted toward the top conductive plate 40, and consequently accumulates beneath the capacitor dielectric 30. If the semiconductor bottom plate (12, 20) is doped with p-type dopants, the accumulation mode occurs if the voltage applied to the semiconductor bottom plate (12, 20) is positive relative to the voltage applied to the conductive top plate 40 (that is, the voltage applied to the conductive top plate 40 is negative relative to the voltage applied to the semiconductor bottom plate (12, 20)). If the semiconductor bottom plate (12, 20) is doped with n-type dopants, as exemplified in FIG. 2, the accumulation mode occurs if the voltage applied to the semiconductor bottom plate (12, 20) is negative relative to the voltage applied to the conductive top plate 40. The thickness of the accumulation layer and the amount of charge in the accumulation layer (which is equal to the amount of charge on the side of the conductive top plate 40) is affected by the doping concentration of the at least one semiconductor pillar 20, the work function of the material in the top semiconductor plate 40, the thickness and the dielectric constant of the capacitor dielectric layer 30, and the bias voltage across the capacitor dielectric 30.

The capacitance of the MOS varactor in the accumulation mode is the sum of the capacitance of the component capacitors formed on the top surface 32 of the at least one semiconductor pillar 20, the capacitance of the component capacitors formed on the sidewall surface 34 of the at least one semiconductor pillar 20, and on the portion of the inter-pillar semiconductor surface 36 which a portion of the capacitor dielectric 30 overlies. Due to the large area of the sidewall surface 34, the capacitance of the MOS varactor according to the present invention is substantially higher than a planar capacitor with similar capacitor dielectric 30 and comparable semiconductor area.

Referring to FIG. 3, the MOS varactor may be put in a depletion mode by applying a voltage bias across the capacitor dielectric 30 such that the majority carriers are repelled away from the capacitor dielectric 30. The voltage bias condition is adjusted such that the width of depletion exceeds half of the minor lateral dimension of the at least one semiconductor pillar 20. This condition completely depletes at least one semiconductor pillar 20 as well as a depletion zone 21 that is formed underneath the capacitor dielectric 30 and underneath the depleted at least one semiconductor pillar 20. Effectively, the only capacitor substantially contributing to the overall capacitance in this mode is the capacitor formed by the portion of the capacitor dielectric 30 that contacts the bottom semiconductor 12. However, this capacitor has a depletion zone 21 as well as the portion of the capacitor dielectric 30 described above between two charged regions, and therefore, has a low capacitance.

According to one aspect of the present invention, the MOS varactor has two types of component capacitors which are connected in parallel. The first type of component capacitors comprise component capacitors that are formed on the top surface 32 and on the sidewall surface 34 of each of the at least one semiconductor pillar 20. The second type of component capacitors comprises the component capacitor on the inter-pillar semiconductor surface 36. In the accumulation mode, the total capacitance of the first type component capacitors is much greater than the capacitance of the second type capacitor, i.e., the component capacitor on the inter-pillar semiconductor surface 36. Therefore, while Cₘₐₓ is determined by the sum of the capacitance of the first type capacitors in the accumulation mode and the capacitance of the second type capacitor in the accumulation mode, the total capacitance of the first type component capacitors dominates Cₘₐₓ. In the depletion mode, however, the capacitance of the first type capacitors is negligible compared to the capacitance of the second type capacitor. In addition, the capacitance of the second type capacitor also decreases in the depletion mode. Therefore, Cₘᵢₙ is determined substantially by the capacitance of the second type capacitor in the depletion mode.

The drastic variation in the capacitance of the first type capacitors is achieved by the geometry of the at least one semiconductor pillar 20 that is conducive to complete depletion under suitable bias conditions. Combination of the variation in the capacitance of the first type capacitors with additional variation in the capacitance of the second type capacitor results in a very high value for the ratio of the maximum capacitance to the minimum capacitance. Therefore, depending on the DC bias condition across the conductive top plate 40 and the semiconductor bottom plate 20, the capacitance and hence the impedance for an AC signal may be altered by orders of magnitude, and consequently results in a very high Q factor for circuit applications.

According to the present invention, the value for the ratio of the maximum capacitance to the minimum capacitance, i.e., Cₘₐₓ/Cₘᵢₙ, may be altered by adjusting process parameters. The process parameters include the doping of the bottom semiconductor 12, the doping of the at least one semiconductor pillar 20, the material and thickness of the capacitor dielectric 30, the material and the doping concentration of the conductive top plate 40, and the height of the at least one semiconductor pillar 20.

According to the present invention, the value for the ratio of the maximum capacitance to the minimum capacitance, i.e., Cₘₐₓ/Cₘᵢₙ, may be altered by adjusting design parameters. The design parameters include the cross-section of each of the at least one semiconductor pillar 20, e.g., the shape and the minor lateral dimension, the number of at least one semiconductor pillar 20 in an array, and the spacing between each of the at least one semiconductor pillar 20 (and subsequently the area of the capacitor dielectric 30 that contacts the bottom semiconductor 20).

The value for the ratio of the maximum capacitance to the minimum capacitance, i.e., Cₘₐₓ/Cₘᵢₙ, may also be altered by modifying the structures of the MOS varactor according to the first embodiment of the present invention.

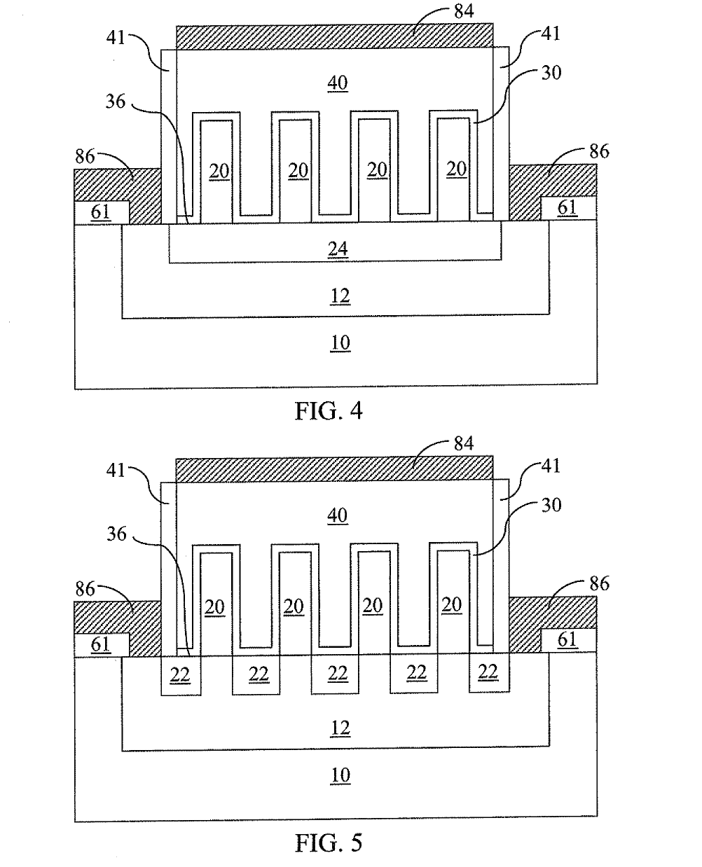

Referring to FIG. 4, a MOS varactor structure according to a second embodiment of the present invention is shown. The semiconductor bottom plate according to the second embodiment comprises a bottom semiconductor 12, a heavily doped semiconductor layer 24, and at least one semiconductor pillar 20. The heavily doped semiconductor layer 24 contacts a bottom surface of each of the at least one semiconductor pillar 20, has a doping concentration in the range from about 1.0×10¹⁸/cm³ to about 3.0×10²¹/cm³, and is contiguous without any hole, i.e., topologically homomorphic to a cube. Preferably, the heavily doped semiconductor layer 24 is a hexahedron wherein all polyhedral angles are 90°, in other words, any horizontal or vertical cross-section of the heavily doped semiconductor layer 24 is a rectangle. The heavily doped semiconductor layer 24 comprises both a volume beneath the bottom(s) of the at least one semiconductor pillar 20 and a volume beneath the inter-pillar semiconductor surface 36. The heavily doped semiconductor layer 24 contacts the bottom inter-pillar semiconductor surface 36. The doping of the heavily doped semiconductor layer 24 is of the same type as the doping of the bottom semiconductor 12. In a depletion mode, due to the presence of the heavily doped semiconductor layer 24, the width of the depletion region decreases and consequently the minimum capacitance Cₘᵢₙ increases while the ratio Cₘₐₓ/Cₘᵢₙ decreases relative to corresponding values for a comparable MOS varactor structure according to the first embodiment of the present invention.

Referring to FIG. 5, a MOS varactor structure according to the third embodiment of the present invention is shown. The semiconductor bottom plate according to the third embodiment comprises a bottom semiconductor 12, a holed heavily doped semiconductor layer 22, and at least one semiconductor pillar 20. The holed heavily doped semiconductor layer 22 is a heavily doped semiconductor layer with holes. The holed heavily doped semiconductor layer 22 does not contact a bottom surface of each of the at least one semiconductor pillar 20, has a doping concentration in the range from about 1.0×10¹⁸/cm³ to about 3.0×10²¹/cm³, and has holes. The number and the shapes of the holes match the number and shapes of the bottom of the at least one semiconductor pillar 20. The holed heavily doped semiconductor layer 22 comprises a volume beneath the inter-pillar semiconductor surface 36 and does not include any volume beneath the bottom(s) of the at least one semiconductor pillar 20. The holed heavily doped semiconductor layer 22 contacts the inter-pillar semiconductor surface 36. The doping of the holed heavily doped semiconductor layer 22 is of the same type as the doping of the bottom semiconductor 12. In a depletion mode, due to the presence of the holed heavily doped semiconductor layer 22, the width of the depletion region decreases and consequently the minimum capacitance Cₘᵢₙ increases while the ratio Cₘₐₓ/Cₘᵢₙ decreases relative to corresponding values for a comparable MOS varactor structure according to the first embodiment of the present invention.

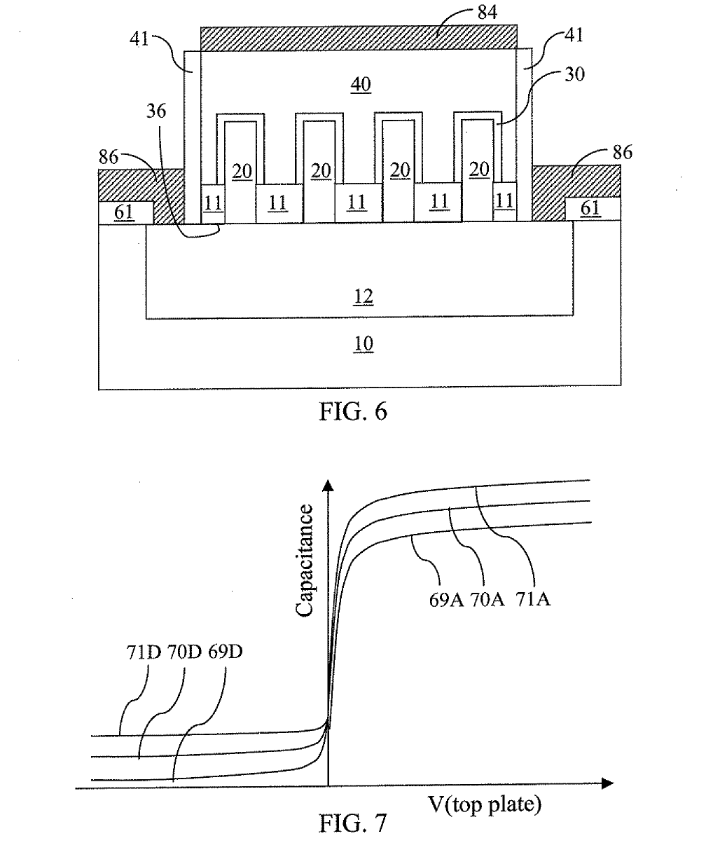

Referring to FIG. 6, a semiconductor structure according to a fourth embodiment of the present invention is shown. A plate insulator 11 is formed on the inter-pillar semiconductor surface 36 for example by deposition of a dielectric insulator layer over the at least one semiconductor pillar 20 followed by patterning and recessing. Alternately, a dielectric insulator layer may be formed prior to selective epitaxial deposition of a material for the at least one semiconductor pillar 20 and not removed completely to form a plate insulator 11. The capacitor dielectric 30 does not contact the inter-pillar semiconductor surface 36. The plate insulator 11 has holes and the number and the shapes of the holes match the number and shapes of the bottom of the at least one semiconductor pillar 20. Due to the presence of the plate insulator 11, the capacitance of the second type capacitor, that is, the capacitor formed by the conductive top plate 40, the plate insulator 11, and the bottom semiconductor 12, is decreased relative to a comparable MOS varactor structure according to the first embodiment of the present invention. Consequently, the minimum capacitance Cₘᵢₙ decreases and the ratio Cₘₐₓ/Cₘᵢₙ increases relative to corresponding values for a comparable MOS varactor structure according to the first embodiment of the present invention.

Unless specifically described above, structural relationships and composition of various components according to the second, third, and fourth embodiments of the present invention are identical to the first embodiment, and therefore, equivalence of elements not specified to be different among the four embodiments are implied herein. Particularly, the at least one semiconductor pillar 20 and the bottom semiconductor 12 comprise a doped single-crystalline semiconductor material having a doping concentration in the range from about 1.0×10¹⁶/cm³ to about 2.0×10²⁰/cm³, and preferably in the range from about 1.0×10¹⁷/cm³ to about 5.0×10¹⁸/cm³ in all of the embodiments of the present invention.

The set-in of the accumulation mode requires a small voltage differential between the conductive top plate and the semiconductor bottom plate as can be seen in FIG. 7, which shows a nominal accumulation mode curve 70A, a nominal depletion mode curve 70D, a top accumulation mode curve 71A, a top depletion mode curve 71D, a bottom accumulation mode curve 69A, and a bottom depletion mode curve 69D, which are collectively identified as capacitance curves (69A, 70A, 71A, 69D, 701D, 71D). The capacitance curves (69A, 70A, 71A, 69D, 70D, 71D) show the variation in the capacitance of exemplary MOS structures as a function of a top plate voltage V (top plate), that is, the voltage bias on the conductive top plate 40 relative to the voltage on the bottom semiconductor 12.

The polarity of the voltage bias needed across the capacitor dielectric 30 to induce an accumulation mode or to induce a depletion mode depends on the doping of the at least one semiconductor pillar 20. Also, the voltage at which a transition occurs between the accumulation mode and the depletion mode (which is about the top plate voltage the ordinate in FIG. 7) depends on the material in the conductive top plate 40.

For example, if the bottom semiconductor 12 has n-type doping, applying a more positive voltage on the top plate relative to the bottom semiconductor induces the accumulation mode. The nominal accumulation mode curve 70A to the right of the ordinate in FIG. 7 illustrates the response of an exemplary nominal MOS varactor in an accumulation mode according to any of the embodiments of the present invention. Applying a more negative voltage on the top plate relative to the bottom semiconductor on the same structure induces a depletion mode. The nominal depletion mode curves 70D to the left of the ordinate in FIG. 7 illustrate the response of the exemplary nominal MOS varactor the produces the nominal accumulation mode curve 70A in the accumulation mode.

An aspect of the present invention, according to which the minimum capacitance Cₘᵢₙ, and consequently, the ratio Cₘₐₓ/Cₘᵢₙ can be changed, is demonstrated with the three depletion mode curves (69D, 70D, 71D) in the depletion mode. The nominal depletion mode curve 70D in the middle of the three depletion mode curves (69D, 70D, 71D) represents the capacitance of the exemplary nominal MOS varactor above. Adjustments on process parameters and design parameters, and/or if applicable, structural changes between embodiments may be employed to increase the minimum capacitance and to obtain a higher depletion mode capacitance as shown by the top depletion mode curve 71D. Alternately, similar adjustments and/or structural changes between embodiments may be employed to decrease the minimum capacitance and to obtain a lower depletion mode capacitance as shown by the bottom depletion mode curve 69D. The minimum capacitance is substantially the second type capacitance as noted above.

When adjustments are made on process parameters and design parameters and/or, if applicable, structural changes between embodiments are made, there is a corresponding change in the maximum capacitance as well as represented by the top accumulation mode curve 71A due to higher second type capacitance or by the bottom accumulation mode curve 69A due to lower second type capacitance. The fractional change in the maximum capacitance is much less compared to the corresponding fractional change in the minimum capacitance. Therefore, the ratio of the maximum capacitance to the minimum capacitance is altered significantly with the change in the second type capacitance, thus enabling a tuning of the ratio Cₘₐₓ/Cₘᵢₙ, and consequently, tailoring of a Q factor of the MOS varactor.

While the invention has been described in terms of specific embodiments, it is evident in view of the foregoing description that numerous alternatives, modifications and variations will be apparent to those skilled in the art. Accordingly, the invention is intended to encompass all such alternatives, modifications and variations which fall within the scope and spirit of the invention and the following claims.

What is claimed is:

1. A metal-oxide-semiconductor (MOS) varactor structure, comprising:
a semiconductor bottom plate having at least one semiconductor pillar and an inter-pillar semiconductor surface, wherein said inter-pillar semiconductor surface contacts at least one sidewall surface of each of said at least one semiconductor pillar;
a capacitor dielectric contacting said at least one semiconductor pillar and said inter-pillar semiconductor surface; and
a conductive top plate contacting said capacitor dielectric.

2. The MOS varactor structure of claim 1, wherein said at least one semiconductor pillar comprises an array of semiconductor pillars in a row and column arrangement and electrically connected to a bottom semiconductor.

3. The MOS varactor structure of claim 2, wherein said at least one semiconductor pillar and said bottom semiconductor comprise doped single-crystalline semiconductor material having a doping concentration in the range from about 1.0×10¹⁶/cm³ to about 2.0×10²⁰/cm³.

4. The MOS varactor structure of claim 3, wherein said at least one semiconductor pillar and said bottom semiconductor comprise a doped single-crystalline semiconductor material having a doping concentration in the range from about 1.0×10¹⁷/cm³ to about 5.0×10¹⁸/cm³.

5. The MOS varactor structure of claim 3, wherein said conductive top plate comprises doped polysilicon having a doping concentration in the range from about 1.0×10¹⁸/cm³ to about 3.0×10²¹/cm³.

6. The MOS varactor structure of claim 3, wherein a cross-sectional area of each of said at least one semiconductor pillar is substantially a rectangle with two major sides with a first length and two minor sides with a second length, wherein said first length is not less than said second length.

7. The MOS varactor structure of claim 6, wherein the height of said at least one semiconductor pillar is greater than said second length.

8. The MOS varactor structure of claim 3, wherein a cross-sectional area of each of said at least one semiconductor pillar is substantially an ellipse.

9. The MOS varactor structure of claim 3, further comprising:
a bottom contact electrically connected to said semiconductor bottom plate;
a top contact electrically connected to said conductive top plate; and
a dielectric spacer contacting sidewalls of said conductive top plate.

10. The MOS varactor structure of claim 3, wherein said bottom plate further comprises a heavily doped semiconductor layer, wherein said heavily doped semiconductor layer contacts a bottom surface of each of said at least one semiconductor pillar, has a doping concentration in the range from about 1.0×10¹⁸/cm³ to about 3.0×10²¹/cm³, and is contiguous without any hole.

11. The MOS varactor structure of claim 3, wherein said bottom plate further comprises a holed heavily doped semiconductor layer, wherein said heavily doped semiconductor layer contacts said capacitor dielectric, does not contact bottom surfaces of said at least one semiconductor pillar, and has a doping concentration in the range from about 1.0×10¹⁸/cm³ to about 3.0×10²¹/cm³.

12. A metal-oxide-semiconductor (MOS) varactor structure, comprising:
a semiconductor bottom plate having at least one semiconductor pillar and an inter-pillar semiconductor surface, wherein said inter-pillar semiconductor surface contacts at least one sidewall surface of each of said at least one semiconductor pillar;
a capacitor dielectric contacting said at least one semiconductor pillar and not contacting said inter-pillar semiconductor surface;
a plate insulator contacting said inter-pillar semiconductor surface and contacting at least one sidewall surface of each of said at least one semiconductor pillar; and
a conductive top plate contacting said capacitor dielectric.

13. The MOS varactor structure of claim 12, wherein said at least one semiconductor pillar comprises an array of semiconductor pillars in a row and column arrangement and is electrically connected to a bottom semiconductor.

14. The MOS varactor structure of claim 13, wherein said at least one semiconductor pillar and said bottom semiconductor comprise doped single-crystalline semiconductor material having a doping concentration in the range from about 1.0×10¹⁶/cm³ to about 2.0×10²⁰/cm³.

15. The MOS varactor structure of claim 14, wherein said at least one semiconductor pillar and said bottom semiconductor comprise doped single-crystalline semiconductor material having a doping concentration in the range from about 1.0×10¹⁷/cm³ to about 5.0×10⁸/cm³.
